(19) United States
(12) Patent Application Publication
(10) Pub. No.: US 2024/0298449 A1
(43) Pub. Date: Sep. 5, 2024

(54) SEMICONDUCTOR DEVICE AND METHOD OF MANUFACTURING SEMICONDUCTOR DEVICE

(71) Applicant: SK hynix Inc., Icheon-si Gyeonggi-do (KR)

(72) Inventor: Jae Ho KIM, Icheon-si Gyeonggi-do (KR)

(73) Assignee: SK hynix Inc., Icheon-si Gyeonggi-do (KR)

(21) Appl. No.: 18/339,681

(22) Filed: Jun. 22, 2023

(30) Foreign Application Priority Data
Mar. 2, 2023 (KR) 10-2023-0027589

(51) Int. Cl. H10B 43/35; H10B 41/27; H10B 41/35; H10B 41/41; H10B 43/27; H10B 43/40

(52) U.S. Cl. CPC H10B 43/35; H10B 41/27; H10B 41/35; H10B 41/41; H10B 43/27; H10B 43/40

(57) ABSTRACT

A semiconductor device includes a source structure, an insulating layer disposed within the source structure, the insulating layer including a first edge that extends in a first direction and a second edge that extends in a second direction, the second direction intersecting the first direction, a first contact structure disposed within the insulating layer, the first contact structure having a second width in the second direction and a first width in the first direction, the first width being greater than the second width, and a second contact structure disposed on the insulating layer and connected to the first contact structure, the second contact structure having a fourth width in the second direction and a third width in the first direction, the third width being greater than the fourth width.

### CROSS-REFERENCE TO RELATED APPLICATION

This application claims priority under 35 U.S.C. § 119 (a) to Korean Patent Application No. 10-2023-0027589 filed on Mar. 2, 2023, in the Korean Intellectual Property Office, which is incorporated herein by reference in its entirety.

### BACKGROUND

### 1. Technical Field

Embodiments relate to an electronic device and a method of manufacturing an electronic device and, more particularly, to a semiconductor device and a method of manufacturing a semiconductor device.

### 2. Related Art

The degree of integration of semiconductor devices is basically determined by the area that is occupied by a unit memory cell. As the improvement of the degree of integration of semiconductor devices in which a memory cell is formed on a substrate as a single layer is reaching its limit, a three-dimensional semiconductor device in which memory cells are stacked on a substrate is proposed. Furthermore, in order to improve operation reliability of such a semiconductor device, various structures and manufacturing methods are being developed.

### SUMMARY

In an embodiment, a semiconductor device may include a source structure, an insulating layer disposed within the source structure, the insulating layer including a first edge that extends in a first direction and a second edge that extends in a second direction, the second direction intersecting the first direction, a first contact structure disposed within the insulating layer, the first contact structure having a second width in the second direction and a first width in the first direction, the first width being greater than the second width, and a second contact structure disposed on the insulating layer and connected to the first contact structure, the second contact structure having a fourth width in the second direction and a third width in the first direction, the third width being greater than the fourth width.

In an embodiment, a semiconductor device may include a peripheral circuit, a source structure disposed on the peripheral circuit, an insulating layer disposed within the source structure, the insulating layer including a first edge that extends in a first direction and a second edge that extends in a second direction, the second direction intersecting the first direction, a first contact structure connected to the peripheral circuit through the insulating layer and disposed to be spaced apart from the first edge by a second distance and to be spaced apart from the second edge by a first distance, the first distance being greater than the second distance, and a second contact structure disposed on the insulating layer, connected to the first contact structure, and disposed to be spaced from the first edge by a fourth distance and to be spaced from the second edge by a third distance, the third distance being greater than the fourth distance.

In an embodiment, a method of manufacturing a semiconductor device may include forming a source structure, forming, within the source structure, an insulating layer including a first edge that extends in a first direction and a second edge that extends in a second direction, the second direction intersecting the first direction, forming, within the insulating layer, a first contact structure having a second width in the second direction and a first width in the first direction, the first width being greater than the second width, forming a stack on the source structure, and forming a second contact structure that extends through the stack and is connected to the first contact structure, the second contact structure having a fourth width in the second direction and a third width in the first direction, the third width being greater than the fourth width.

In an embodiment, a method of manufacturing a semiconductor device may include forming a peripheral circuit, forming a source structure on the peripheral circuit, forming, within the source structure, an insulating layer including a first edge that extends in a first direction and a second edge that extends in a second direction, the second direction intersecting the first direction, forming a first contact structure that is connected to the peripheral circuit through the insulating layer and that is disposed to be spaced apart from the first edge by a second distance and to be spaced apart from the second edge by a first distance, the first distance being greater than the second distance, forming a stack on the source structure, and forming a second contact structure that extends through the stack and is connected to the first contact structure, the second contact structure being disposed to be spaced apart from the first edge by a fourth distance and that is disposed to be spaced apart from the second edge by a third distance, the third distance being greater than the fourth distance.

### BRIEF DESCRIPTION OF THE DRAWINGS

FIGS. 1A to 1D are diagrams for describing a semiconductor device according to an embodiment of the present disclosure.

FIGS. 2A to 2D, 3A to 3D, 4A to 4D, and 5A to 5D are diagrams for describing a method of manufacturing a semiconductor device according to an embodiment of the present disclosure.

### DETAILED DESCRIPTION

Hereinafter, embodiments according to the technical spirit of the present disclosure are described with reference to the accompanying drawings.

An embodiment of the present disclosure provides a semiconductor device having a stable structure and improved characteristics and a method of manufacturing a semiconductor device.

According to the present technology, the semiconductor device having a stable structure and improved reliability can be provided.

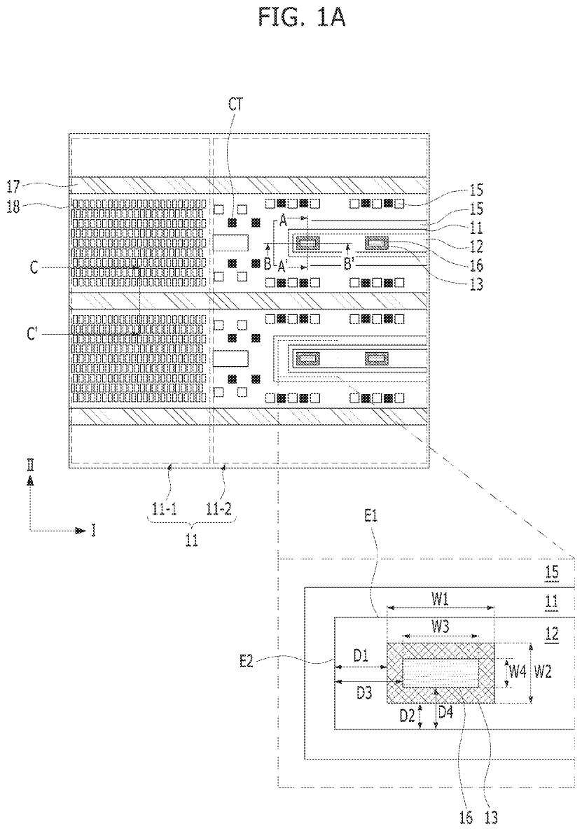

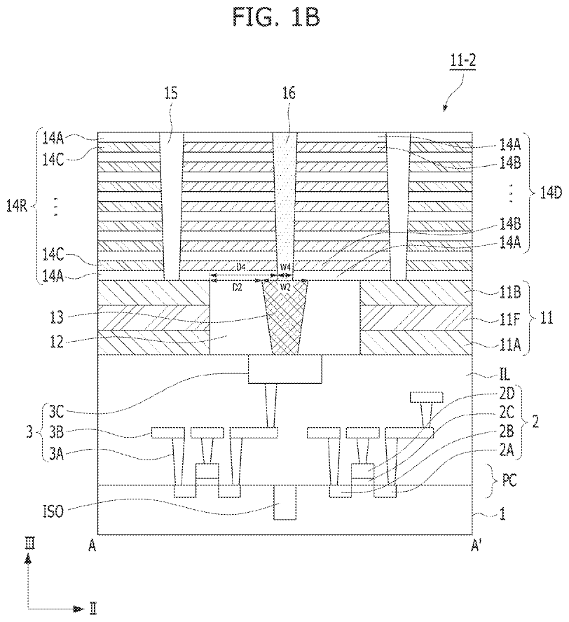

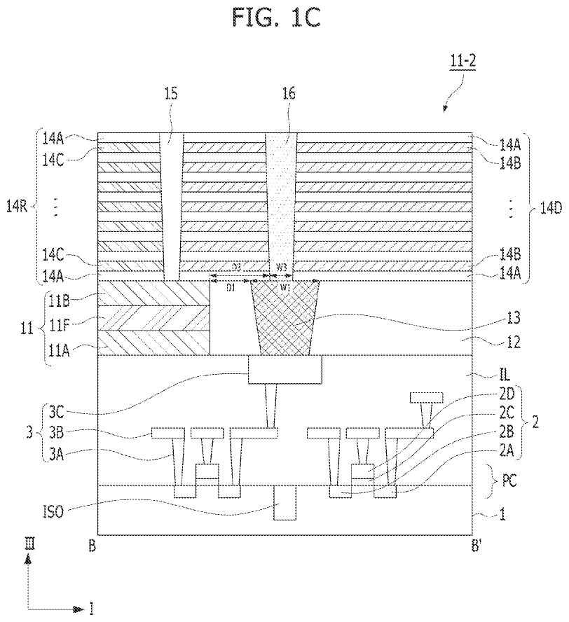

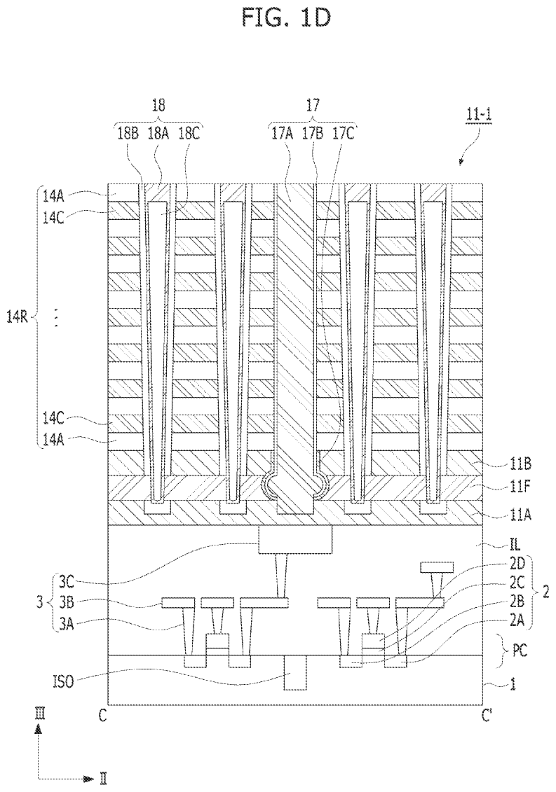

FIGS. 1A to 1D are diagrams for describing a semiconductor device according to an embodiment of the present disclosure. FIG. 1A may be a plan view of the semiconductor device. FIG. 1B may be a cross-sectional view taken along line A-A′ in FIG. 1A. FIG. 1C may be a cross-sectional view taken along line B-B′ in FIG. 1A. FIG. 1D may be a cross-sectional view taken along line C-C′ in FIG. 1A.

Referring to FIGS. 1A to 1C, the semiconductor device may include a source structure 11, an insulating layer 12, or a first contact structure 13, or a combination thereof. The semiconductor device may further include a substrate 1, a peripheral circuit PC, an interlayer insulating layer IL, an interconnection structure 3, a gate structure 14R, a dummy structure 14D, a support 15, a second contact structure 16, a source contact structure 17, or a channel structure 18, or a combination thereof.

The source structure 11 may include a cell area 11_1 or a connection area 11_2, or a combination thereof. The connection area 11_2 of the source structure 11 may include a first source layer 11A, a second source layer 11B, or a third source layer 11F or a combination thereof. The source structure 11 may include a conductive material, such as polysilicon or metal.

The peripheral circuit PC may be disposed under the source structure 11. The peripheral circuit PC may be disposed under the cell area 11_1 or connection area 11_2 of the source structure 11. The peripheral circuit PC may be disposed on the substrate 1. An isolation layer ISO may be disposed within the substrate 1. An active area may be defined by the isolation layer ISO. The peripheral circuit PC may include a transistor 2, a capacitor, or a register. For example, the transistor 2 may include a first junction 2A, a second junction 2B, a gate insulating layer 2C, or a gate electrode 2D. The gate insulating layer 2C may be disposed between the gate electrode 2D and the substrate 1. The gate insulating layer 2C and the isolation layer ISO may include an insulating material, such as oxide or nitride.

The interconnection structure 3 may be disposed under the source structure 11. The interconnection structure 3 may include contact plugs 3A, wires 3B, or a connection pad 3C. The interlayer insulating layer IL may be disposed between the substrate 1 and the source structure 11. The interconnection structure 3 may be disposed within the interlayer insulating layer IL. The interconnection structure 3 may be electrically connected to the peripheral circuit PC. For example, the interconnection structure 3 may be electrically connected to the transistor 2. Each of the contact plugs 3A may connect each of the junctions 2A and 2B of the transistor 2 with the wire 3B, mutually connect the wires 3B, or connect the wire 3B with the connection pad 3C. Furthermore, each of the contact plugs 3A may connect the gate electrode 2D and the wire 3B. The contact plugs 3A, the wires 3B, or the connection pad 3C may include a conductive material, such as tungsten, aluminum, or copper.

The insulating layer 12 may be disposed within the source structure 11. The insulating layer 12 may include a first edge E1 that extends in a first direction I and a second edge E2 that extends in a second direction II, the second direction II intersecting the first direction I. The insulating layer 12 may have a uniform width or may have different widths depending on a level of the insulating layer 12. For example, the insulating layer 12 may have a tapered cross section, the width of which is decreased toward an upper side of the insulating layer 12. The insulating layer 12 may insulate the first contact structure 13 and the source structure 11. The insulating layer 12 may include an insulating material, such as oxide or nitride.

The first contact structure 13 may be disposed within the insulating layer 12. For example, the sidewall of the first contact structure 13 may be surrounded by the insulating layer 12. The first contact structure 13 and the peripheral circuit PC may be connected by the interconnection structure 3. The first contact structure 13 may have a uniform width or may have different widths depending on a level of the first contact structure 13. For example, the first contact structure 13 may have a tapered cross section, the width of which is decreased toward a lower side of the first contact structure 13.

The first contact structure 13 may have a first width W1 in the first direction I and a second width W2 in the second direction II. In this case, the first width W1 and the second width W2 may be the width of an upper surface of the first contact structure 13, the width of a lower surface of the first contact structure 13, or an average width of the widths of the upper surface and lower surface of the first contact structure 13. The first width W1 and the second width W2 may be substantially the same or may be different from each other. The first width W1 may be 1 to 2 times greater than the second width W2. For example, the first width W1 may be greater than the second width W2, and the first width W1 may be about 1.5 times greater than the second width W2.

If the first width W1 and second width W2 of the first contact structure 13 are identical with each other, the first contact structure 13 may be misaligned or tilted in the first direction I or the second direction II in a process of manufacturing the semiconductor device. Accordingly, according to the present disclosure, as the first width W1 of the first contact structure 13 is formed to be relatively greater than the second width W2 of the first contact structure 13, misalignment between the first contact structure 13 and the source structure 11 in the second direction II can be prevented or reduced, and the tilting of the first contact structure 13 can be prevented or reduced.

The first contact structure 13 may be disposed to be spaced apart from the first edge E1 of the insulating layer 12 by a second distance D2 and from the second edge E2 of the insulating layer 12 by a first distance D1. In this case, the first distance D1 may be a distance from the second edge E2 to the sidewall of the first contact structure 13. The second distance D2 may be a distance from the first edge E1 to the sidewall of the first contact structure 13. In this case, the sidewall may be the sidewall of the upper surface of the first contact structure 13, may be the sidewall of the lower surface of the first contact structure 13, or may be the sidewall of a middle surface between the upper surface and the lower surface of the first contact structure 13.

Alternatively, the first distance D1 and the second distance D2 may each be an average distance from the second edge E2 to the corresponding sidewall of the first contact structure 13 and the first edge E1 to the corresponding sidewall of the first contact structure 13. For example, the first distance D1 may be an average distance of the distance from the second edge E2 to the sidewall of the upper surface of the first contact structure 13 and the distance from the second edge E2 to the sidewall of the lower surface of the first contact structure 13. Also, the second distance D2 may be an average distance of the distance from the first edge E1 to the sidewall of the upper surface of the first contact structure 13 and the distance from the first edge E1 to the sidewall of the lower surface of the first contact structure 13.

In a plane view, the first distance D1 between the second edge E2 and the first contact structure 13 may varies. In this case, the first distance D1 may be an average distance between the second edge E2 to the corresponding sidewall of the first contact structure 13. Also, the second distance D2 between the first edge E1 and the first contact structure 13 may varies. In this case, the second distance D2 may be an average distance between the first edge E1 to the corresponding sidewall of the first contact structure 13.

The first distance D1 may be substantially the same as the second distance D2 or may be different from the second distance D2. The first distance D1 may be greater than the second distance D2. Furthermore, the first distance D1 and the second distance D2 may be substantially the same as the first width W1 or the second width W2 or may be different from the first width W1 or the second width W2. For example, the second distance D2 may be substantially the same as the second width W2. The first contact structure 13 may include a conductive material, such as tungsten.

If the first contact structure 13 is disposed to be adjacent to the first edge E1 or the second edge E2, the first contact structure 13 that has been misaligned or tilted may come into contact with the source structure 11, and a bridge may occur between the first contact structure 13 and the source structure 11. Accordingly, a contact between the first contact structure 13 and the source structure 11 can be reduced 55 the first contact structure 13 is misaligned or tilted due to the first contact structure 13 having an increased first distance D1 from the second edge E2. For example, the first contact structure 13 may be disposed so that the first distance D1 is greater than the second distance D2. Furthermore, as the first contact structure 13 is disposed to be spaced apart from the first edge E1 by the second distance D2 that is substantially the same as the second width W2, the occurrence of a bridge between the first contact structure 13 and the source structure 11 in the second direction II can be prevented or reduced.

The gate structure 14R may be disposed on the source structure 11. For example, the gate structure 14R may be disposed in the cell area 11_1 of the source structure 11. The gate structure 14R may extend up to the connection area 11_2. The gate structure 14R may include insulating layers 14A and conductive layers 14C that are alternately stacked. The insulating layer 14A may include an insulating material, such as oxide. The conductive layers 14C may include a conductive material, such as polysilicon, tungsten, or molybdenum.

The dummy structure 14D may be disposed on the source structure 11. For example, the dummy structure 14D may be disposed on the connection area 11_2 of the source structure 11. The dummy structure 14D may include insulating layers 14A and sacrificial layers 14B that are alternately stacked. The sacrificial layers 14B may remain without being substituted with the conductive layers 14C in a process of manufacturing the semiconductor device. The dummy structure 14D may be connected to the gate structure 14R. For example, the insulating layers 14A of the dummy structure 14D and the insulating layers 14A of the gate structure 14R may be mutually connected to form a single layer. The sacrificial layer 14B may include a sacrificial material, such as nitride.

The support 15 may be disposed within the gate structure 14R or the dummy structure 14D and may be disposed on the source structure 11. For example, the support 15 may be disposed in the connection area 11_2 of the source structure 11. The support 15 may have a plug form. The support 15 may have a form, such as a circle, an ellipse, or a polygon. Furthermore, the support 15 may have a form that extends in the first direction I or the second direction II or may have a form, such as a letter U or a letter O. In a process of substituting the sacrificial layers 14B with the conductive layers 14C, the support 15 can prevent the dummy structure 14D or the gate structure 14R from being tilted or can reduce the tilting of the dummy structure 14D or the gate structure 14R. The support 15 may include an insulating material, such as oxide, nitride, or an air gap.

The second contact structure 16 may be disposed within the dummy structure 14D. The second contact structure 16 may extend through the dummy structure 14D and may be connected to the first contact structure 13. The second contact structure 16 and the peripheral circuit PC may be connected through the interconnection structure 3. For example, the second contact structure 16 may be connected to the peripheral circuit PC through the first contact structure 13 and the interconnection structure 3. The second contact structure 16 may have a structure similar to the first contact structure 13. For example, the second contact structure 16 may have a uniform width or may have different widths depending on a level of the second contact structure 16 and may have a tapered cross section, the width of which is decreased toward a lower side of the second contact structure 16.

The second contact structure 16 may have a third width W3 in the first direction I and a fourth width W4 in the second direction II. In this case, the third width W3 and the fourth width W4 may be the widths of an upper surface of the second contact structure 16, the widths of a lower surface of the second contact structure 16, or an average width of the widths of the upper surface and lower surface of the second contact structure 16. The third width W3 and the fourth width W4 may be substantially the same or may be different from each other. The third width W3 may be 1 to 2 times greater than the fourth width W4. For example, the third width W3 may be greater than the fourth width W4, and the third width W3 may be about 1.5 times greater than the fourth width W4. As the third width W3 is formed to be relatively greater than the fourth width W4, the misalignment or tilting of the second contact structure 16 in the second direction II can be prevented or reduced.

If the third width W3 and fourth width W4 of the second contact structure 16 are identical with each other, the second contact structure 16 may be misaligned or tilted in the first direction I or the second direction II in a process of manufacturing the semiconductor device. In such a case, the second contact structure 16 may be offset at a target location, and the central axis of the second contact structure 16 may be tilted. If the aspect ratio of the second contact structure 16 is great, a tilted lower part of the second contact structure 16 may come into contact with the source structure 11 so that a bridge may occur between the second contact structure 16 and the source structure 11. Accordingly, a form of the second contact structure 16 may be changed so that the misalignment or tilting of the second contact structure 16 is prevented or reduced. According to the present disclosure, a location of the second contact structure 16 can be prevented from being offset or tilted in the second direction II or the offsetting or tilting of the second contact structure 16 in the second direction II can be reduced by forming the second contact structure 16 in a form in which the third width W3 is greater than the fourth width W4.

Furthermore, the widths W3 and W4 of the second contact structure 16 may be substantially the same as or different from the widths W1 and W2 of the first contact structure 13. For example, the third width W3 may be smaller than the first width W1, and the fourth width W4 may be smaller than the second width W2. Misalignment between the first contact structure 13 and the second contact structure 16 can be prevented or reduced by forming the widths W3 and W4 of the second contact structure 16 to be smaller than the widths W1 and W2 of the first contact structure 13.

The second contact structure 16 may be disposed to be spaced apart from the first edge E1 of the insulating layer 12 by a fourth distance D4 and from the second edge E2 of the insulating layer 12 by a third distance D3. In this case, the third distance D3 may be a distance from the second edge E2 to the sidewall of the second contact structure 16. The fourth distance D4 may be a distance from the first edge E1 to the sidewall of the second contact structure 16. In this case, the sidewall may be the sidewall of the upper surface of the second contact structure 16, may be the sidewall of the lower surface of the second contact structure 16, or may be the sidewall of a middle surface between the upper surface and the lower surface of the second contact structure 13.

Alternatively, the third distance D3 and the fourth distance D4 may each be an average distance from the second edge E2 to the corresponding sidewall of the second contact structure 16 and the first edge E1 to the corresponding sidewall of the second contact structure 16. For example, the third distance D3 may be an average distance of the distance from the second edge E2 to the sidewall of the upper surface of the second contact structure 16 and the distance from the second edge E2 to the sidewall of the lower surface of the second contact structure 16. Also, the fourth distance D4 may be an average distance of the distance from the first edge E1 to the sidewall of the upper surface of the second contact structure 16 and the distance from the first edge E1 to the sidewall of the lower surface of the second contact structure 16.

In a plane view, the third distance D3 between the second edge E2 and the second contact structure 16 may varies. In this case, the third distance D3 may be an average distance between the second edge E2 to the corresponding sidewall of the second contact structure 16. Also, the fourth distance D4 between the first edge E1 and the second contact structure 16 may varies. In this case, the fourth distance D4 may be an average distance between the first edge E1 to the corresponding sidewall of the second contact structure 13.

The third distance D3 may be substantially the same as or different from the fourth distance D4. For example, the third distance D3 may be greater than the fourth distance D4. The third distance D3 and the fourth distance D4 may each be substantially the same as or different from the first distance D1 or the second distance D2. For example, the third distance D3 may be greater than the first distance D1, and the fourth distance D4 may be greater than the second distance D2.

Furthermore, the third distance D3 and the fourth distance D4 may each be substantially the same as or different from the first width W1, the second width W2, the third width W3, or the fourth width W4. For example, the fourth distance D4 may be substantially the same as the second width W2. The second contact structure 16 may include a conductive material, such as tungsten.

If the second contact structure 16 is disposed to be adjacent to the first edge E1 or the second edge E2, the second contact structure 16 that has been misaligned or tilted may come into contact with the source structure 11, and a bridge may occur between the second contact structure 16 and the source structure 11. Accordingly, a location of the second contact structure 16 may be adjusted by considering the misalignment or tilting of the second contact structure 16. A contact between the second contact structure 16 and the source structure 11 can be reduced even though the second contact structure 16 is misaligned or tilted due to the second contact structure 16 having an increased third distance D3 between the second edge E2 of the insulating layer 12 and the second contact structure 16. For example, the second contact structure 16 may be disposed so that the third distance D3 is greater than the fourth distance D4. Furthermore, the occurrence of a bridge between the second contact structure 16 and the source structure 11 in the second direction II can be prevented or reduced by disposing the second contact structure 16 to be spaced apart from the source structure 11 by the fourth distance D4 that is substantially the same as the second width W2.

Referring to FIGS. 1A and 1D, the channel structures 18 may be disposed within the gate structure 14R. For example, the channel structures 18 may extend through the gate structure 14R and may be connected to the source structure 11. Each of the channel structures 18 may include a channel layer 18A. Each of the channel structures 18 may further include at least one of a memory layer 18B that surrounds the sidewall of the channel layer 18A or an insulating core 18C within the channel layer 18A. The channel layer 18A may include a semiconductor material, such as silicon or germanium. The memory layer 18B may include a blocking layer, a data storage layer, or a tunneling layer, or a combination thereof. The insulating core 18C may include an insulating material, such as oxide, nitride, or an air gap. Each of the channel structures 18 may be connected to the source structure 11. For example, the channel layer 18A and the source structure 11 may be directly connected, or the channel layer 18A and the source structure 11 may be connected through a semiconductor pattern that has been grown through an epitaxial process.

The source contact structure 17 may extend through the gate structure 14R and may be connected to the cell area 11_1 of the source structure 11. The source contact structures 17 may extend in the first direction I and may be spaced apart from each other and arranged in the second direction II. Each of the source contact structures 17 may have a line form.

Each of the source contact structures 17 may include a source contact plug 17A. The source contact plug 17A may extend through the gate structure 14R and may be connected to the cell area 11_1 or connection area 11_2 of the source structure 11. For example, the source contact plug 17A may extend through the gate structure 14R and may be connected to the first source layer 11A in the cell area 11_1 or connection area 11_2 of the source structure 11. The source contact plug 17A may include polysilicon or metal.

Each of the source contact structures 17 may further include a first spacer 17B or a second spacer 17C, or a combination thereof. The first spacer 17B may surround the sidewall of the source contact plug 17A. For example, the first spacer 17B may be disposed between the source contact plug 17A and the gate structure 14R, between the source contact plug 17A and the second source layer 11B, and between the source contact plug 17A and the third source layer 11F. The second spacer 17C may surround a part of the sidewall of the first spacer 17B. For example, the second spacer 17C may be disposed between the first spacer 17B and the second source layer 11B and between the first spacer 17B and the third source layer 11F. The first spacer 17B or the second spacer 17C may include an insulating material, such as oxide, nitride, or an air gap.

Contact plugs CT may be disposed in the connection area 11_2 of the source structure 11. Each of the contact plugs CT may be connected to the conductive layer 14C of the gate structure 14R that is exposed through a stair structure. For example, each of the contact plugs CT may be connected to a word line, a drain selection line, or a source selection line. Each of the contact plugs CT may be connected to the peripheral circuit PC. For example, each of the contact plugs CT may be connected to the transistor 2. The contact plugs CT may include a conductive material, such as tungsten.

According to the aforementioned structure, the second contact structure 16 may have a form in which the third width W3 is greater than the fourth width W4. Accordingly, the offsetting and tilting of the second contact structure 16 having a great aspect ratio in the second direction II can be reduced. Furthermore, the second contact structure 16 may be disposed so that the third distance D3 is greater than the fourth distance D4. Accordingly, the occurrence of a bridge between the second contact structure 16 and the source structure 11 can be reduced even though the second contact structure 16 is offset or tilted in the first direction I.

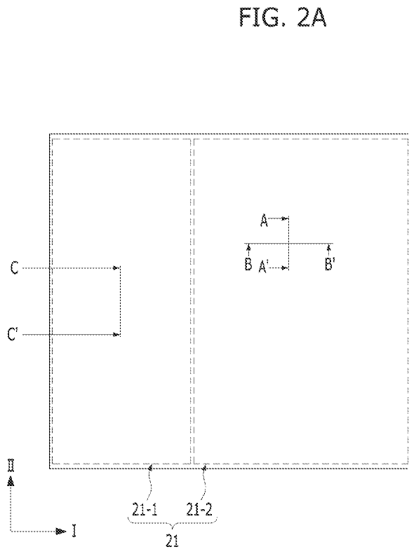

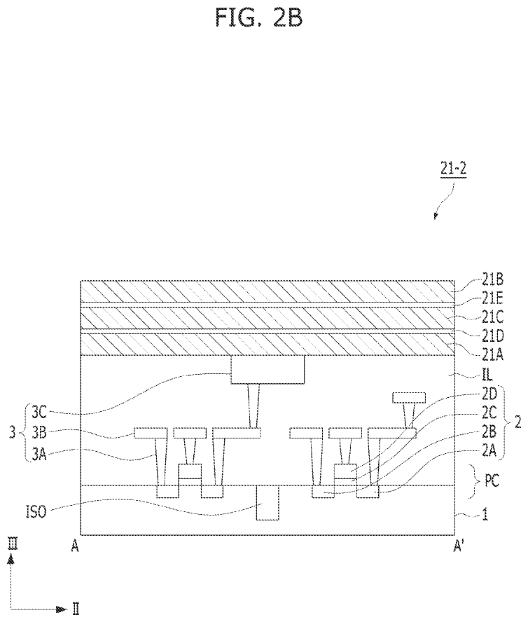

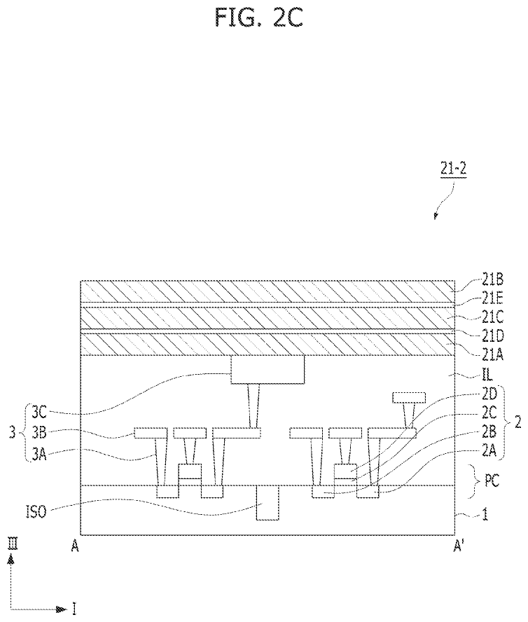

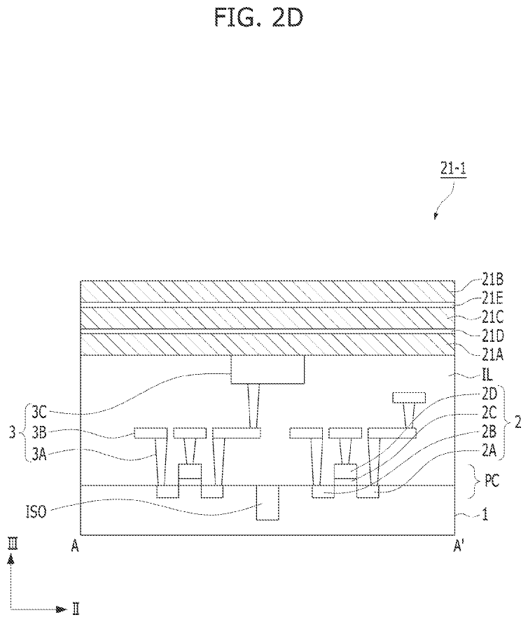

FIGS. 2A to 2D, 3A to 3D, 4A to 4D, and 5A to 5D are diagrams for describing a method of manufacturing a semiconductor device according to an embodiment of the present disclosure. FIGS. 2A, 3A, 4A, and 5A may each be a plan view of the semiconductor device. FIGS. 2B, 3B, 4B, and 5B may each be a cross-sectional view taken along in A-A′ in each of FIGS. 2A, 3A, 4A, and 5A. FIGS. 2C, 3C, 4C, and 5C may each be a cross-sectional view taken along line B-B′ in each of FIGS. 2A, 3A, 4A, and 5A. FIGS. 2D, 3D, 4D, and 5D may each be a cross-sectional view taken along line C-C′ in each of FIGS. 2A, 3A, 4A, and 5A. Hereinafter, a description of contents that are redundant with the aforementioned contents will be omitted.

Referring to FIGS. 2A to 2D, a source structure 21 may be formed. The source structure 21 may include a cell area 21_1 or a connection area 21_2 or may include the cell area 21_1 or the connection area 21_2 in combination. The source structure 21 may include a first source layer 21A, a first passivation layer 21D, a source sacrificial layer 21C, a second passivation layer 21E, or a combination thereof. The source sacrificial layer 21C may be for securing a space for forming a third source layer in a subsequent process. The source structure 21 may include a conductive material, such as polysilicon or metal. The first passivation layer 21D or the second passivation layer 21E may include an insulating material, such as oxide or nitride.

For reference, before the source structure 21 is formed, a peripheral circuit PC or the interconnection structure 3, or a combination thereof, may be formed or the peripheral circuit PC. The peripheral circuit PC or the interconnection structure 3 may be formed on a substrate 1.

An isolation layer ISO may be formed within the substrate 1. An active area may be defined by the isolation layer ISO. The peripheral circuit PC may include a transistor 2, a capacitor, or a register. For example, the transistor 2 may include a first junction 2A, a second junction 2B, a gate insulating layer 2C, and/or a gate electrode 2D. The gate insulating layer 2C and the isolation layer ISO may include an insulating material, such as oxide or nitride. The interconnection structure 3 may include contact plugs 3A, wires 3B, and/or a connection pad 3C. The interconnection structure 3 may include a conductive material, such as tungsten.

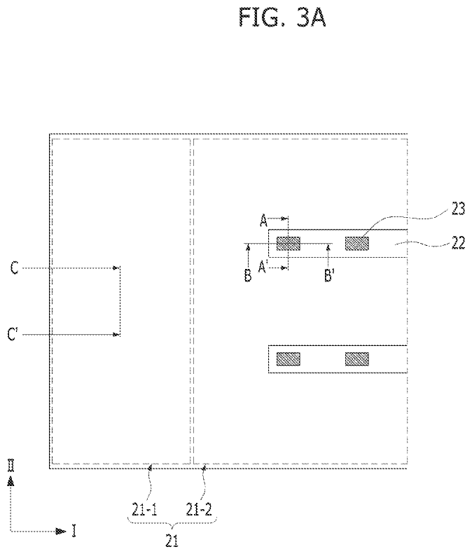

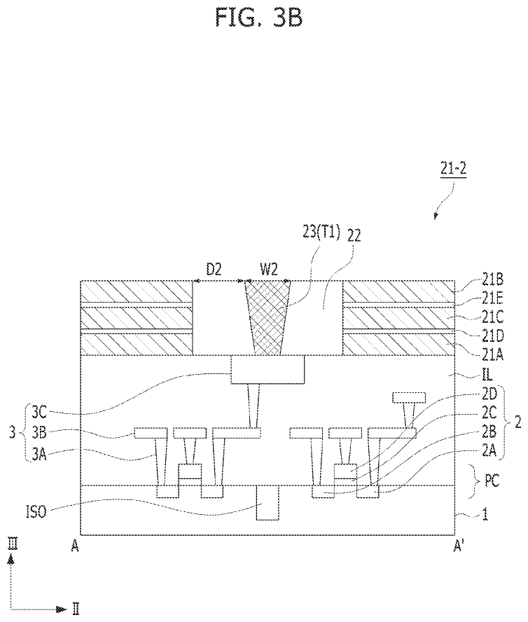

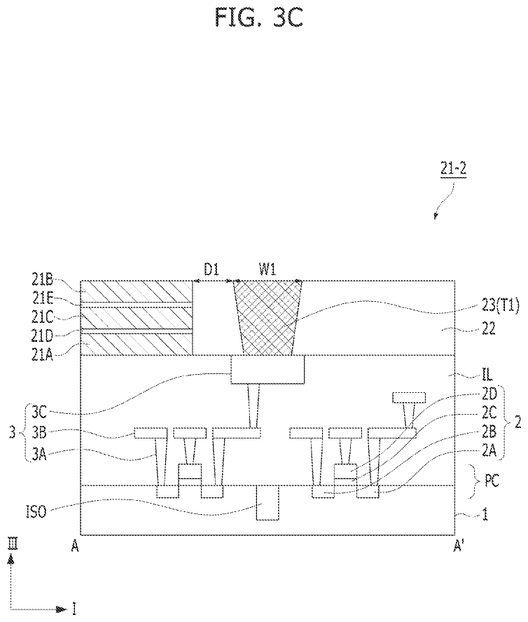

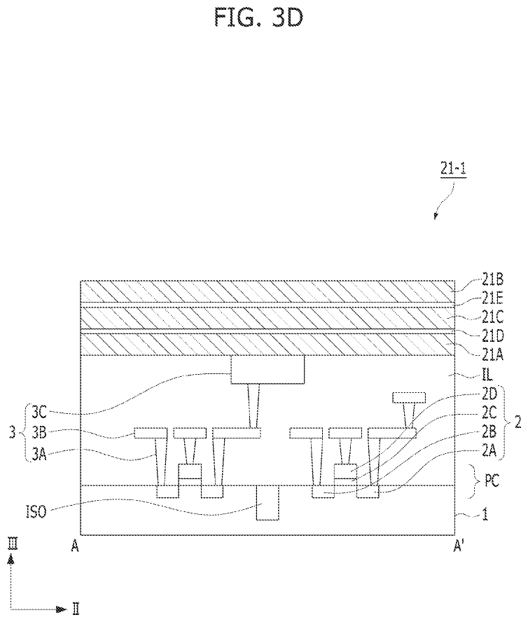

Referring to FIGS. 3A to 3D, an insulating layer 22 may be formed within a source structure 21. For example, the insulating layer 22 may be formed in a connection area 21_2 of the source structure 21. The insulating layer 22 may include a first edge E1 that extends in a first direction I and a second edge E2 that extends in a second direction II, the second direction II intersecting the first direction I. The insulating layer 22 may have a uniform width or may have different widths depending on a level of the insulating layer 22. For example, the insulating layer 22 may have a tapered cross section the width of which is decreased toward an upper side of the insulating layer 22. The insulating layer 22 may include an insulating material, such as oxide or nitride.

Next, a first contact structure 23 may be formed within the insulating layer 22. First, a first trench T1 may be formed within the insulating layer 22. The first trench T1 may be for forming a first contact structure 23 that is directly connected to an interconnection structure 3. The first trench T1 may expose the interconnection structure 3. Next, the first contact structure 23 may be formed within the first trench T1.

The first trench T1 may have a uniform width or may have different widths depending on a level of the first trench T1 and may have a taper, the width of which is narrowed toward a lower side of the first trench T1. The first trench T1 may have a first width W1 in the first direction I and a second width W2 in the second direction II. The first width W1 and the second width W2 may be substantially the same or may be different from each other. The first width W1 may be 1 to 2 times greater than the second width W2. For example, the first width W1 may be about 1.5 times greater than the second width W2. Since the first contact structure 23 is formed within the first trench T1, the first contact structure 23 may also have the first width W1 and the second width W2.

If the first width W1 and second width W2 of the first trench T1 are identical with each other, the first trench T1 may be misaligned or tilted in the first direction I or the second direction II. Accordingly, according to the present disclosure, since the first width W1 of the first trench T1 is formed to be relatively greater than the second width W2, the misalignment of the first trench T1 in the second direction II can be prevented or reduced, and the exposure of the source structure 21 by the first trench T1 can be prevented or reduced.

The first contact structure 23 may be formed to be spaced apart from the first edge E1 of the insulating layer 22 by a second distance D2 and being spaced apart from the second edge E2 of the insulating layer 22 by a first distance D1. In this case, the first distance D1 may be a distance from the second edge E2 to the sidewall of the first contact structure 23. The second distance D2 may be a distance from the first edge E1 to the sidewall of the first contact structure 23. In this case, the sidewall may be the sidewall of an upper surface of the first contact structure 23, may be the sidewall of a lower surface of the first contact structure 23 or may be the sidewall of a middle surface between the upper surface and the lower surface of the first contact structure 23. Alternatively, the first distance D1 and the second distance D2 may each be an average distance from the second edge E2 to the corresponding sidewall of the first contact structure 23 and the first edge E1 to the corresponding sidewall of the first contact structure 23. In a plane view, the first distance D1 between the second edge E2 and the first contact structure 23 may varies. Also, the second distance D2 between the first edge E1 and the first contact structure 23 may varies.

The first distance D1 may be substantially the same as or different from the second distance D2. The first distance D1 may be greater than the second distance D2. Furthermore, the first distance D1 and the second distance D2 may each be substantially the same as or different from the first width W1 or the second width W2. For example, the second distance D2 may be substantially the same as the second width W2.

If the first contact structure 23 is formed to be adjacent to the first edge E1 or the second edge E2, the first contact structure 23 that has been misaligned or tilted may come into contact with the source structure 21, and a bridge may occur between the first contact structure 23 and the source structure 21. Accordingly, a contact between the first contact structure 23 and the source structure 21 can be reduced even though the first contact structure 23 is misaligned or tilted due to the first contact structure 23 having an increased first distance D1 from the second edge E2. For example, the first contact structure 23 may be formed so that the first distance D1 is greater than the second distance D2. Furthermore, since the first contact structure 23 is formed to be spaced apart by the second distance D2 that is substantially the same as the second width W2, the occurrence of a bride between the first contact structure 23 and the source structure 21 in the second direction II can be prevented or reduced.

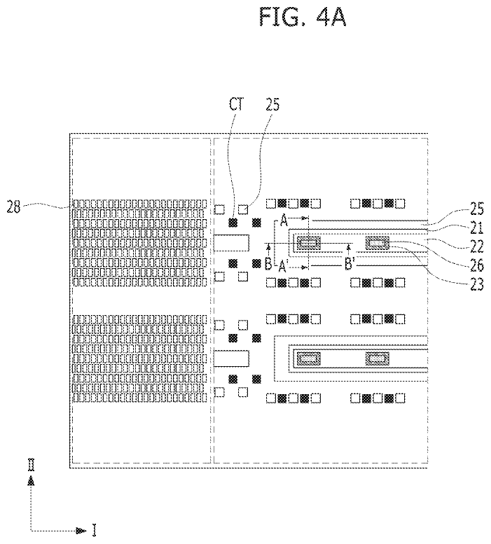

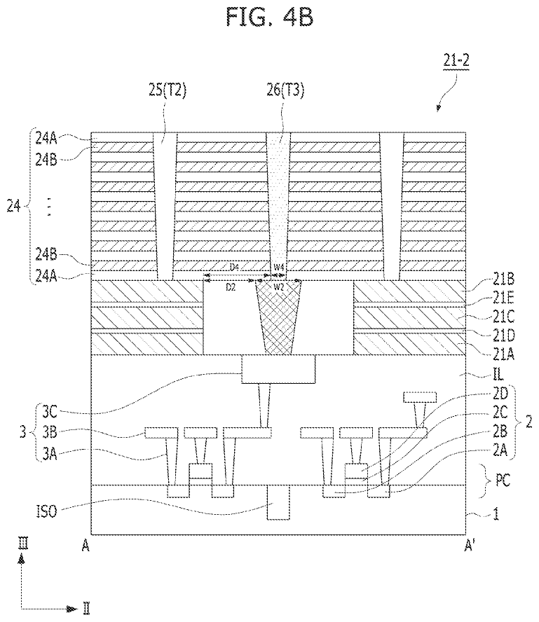

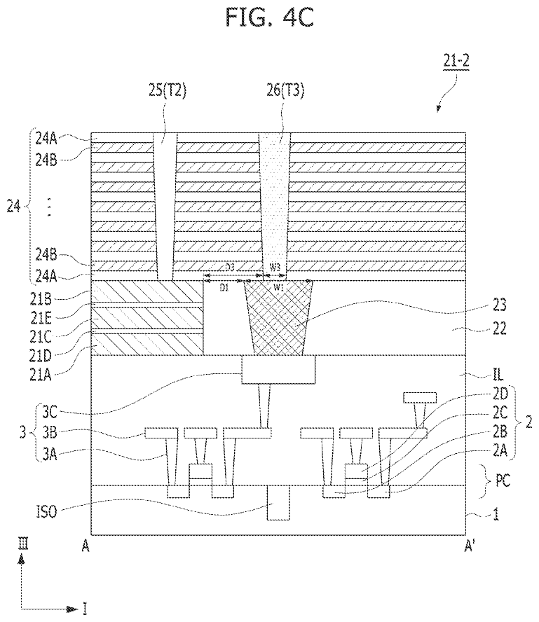

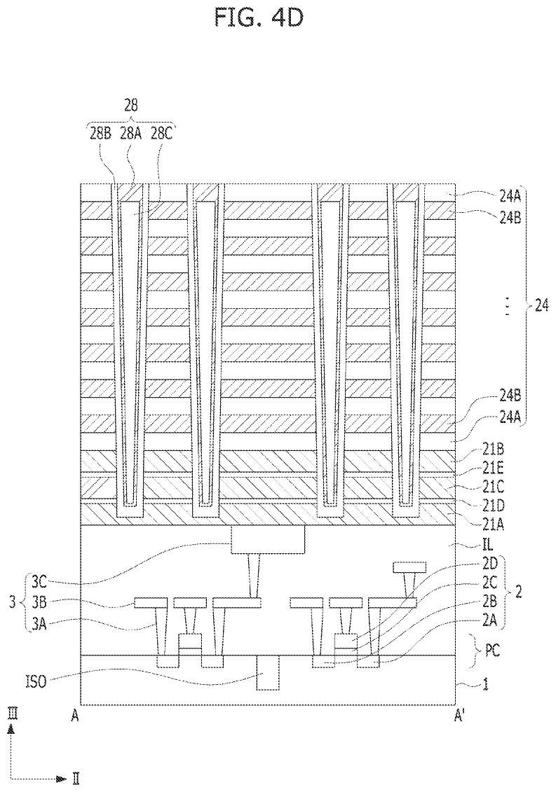

Referring to FIGS. 4A to 4D, a stack 24 may be formed on the source structure 21. The stack 24 may be formed in a cell area 21_1 of the source structure 21. The stack 24 may be expanded up to the connection area 21_2 of the source structure 21. The stack 24 may include first material layers 24A and second material layers 24B that are alternately stacked. The first material layers 24A may include an insulating material, such as oxide. The second material layers 24B may include a sacrificial material, such as nitride, or may include a conductive material, such as polysilicon, tungsten, or molybdenum.

Next, second trenches T2 may be formed on the source structure 21. For example, the second trenches T2 that extend through the stack 24 and that expose the connection area 21_2 of the source structure 21 may be formed. The second trenches T2 may be for forming supports 25. Next, the supports 25 may be formed within the second trenches T2, respectively. The support 25 may have a plug form. The support 25 may have a form, such as a circle, an ellipse, or a polygon. Furthermore, the support 25 may have a form that extends in a first direction I or a second direction II or may have a form, such as a letter U or a letter O. The support 25 may include an insulating material, such as oxide, nitride, or an air gap.

Third trenches T3 may be formed on the source structure 21. For example, the third trenches T3 that extend through the stack 24 and that expose a first contact structure 23 may be formed. The third trenches T3 may be for forming second contact structures 26.

The third trenches T3 may have a uniform width or may have different widths depending on levels of the third trenches and may each have a taper, the width of which is narrowed toward a lower side of the third trench T3. The third trenches T3 may each have a third width W3 in the first direction I and a fourth width W4 in the second direction II. The third width W3 and the fourth width W4 may be substantially the same or may be different from each other. The third width W3 may be 1 to 2 times greater than the fourth width W4. For example, the third width W3 may be greater than the fourth width W4, and the third width W3 may be about 1.5 times greater than the fourth width W4.

If the third width W3 and fourth width W4 of each of the third trenches T3 are identically formed, the third trenches T3 may be misaligned or tilted in the first direction I or the second direction II in a process of forming the third trenches T3. If the aspect ratio of each of the third trenches T3 is great, the third trenches T3 may be formed in the state in which the third trenches T3 have been misaligned or tilted. If the second contact structures 26 are formed within the third trenches T3, respectively, a bridge may occur because a lower part of the second contact structure 26 comes into contact with the source structure 21. Accordingly, in order to prevent or reduce the bridge between the second contact structure 26 and the source structure 21, a form of the third trenches T3 may be changed. For example, according to the present disclosure, the offsetting or tilting of a location of the second contact structure 26 in the second direction II can be prevented or reduced by forming the third trenches T3 in a form in which the third width W3 is greater than the fourth width W4.

Furthermore, the third trenches T3 may each be formed to be spaced apart from the first edge E1 of the insulating layer 22 by a fourth distance D4 and from the second edge E2 of the insulating layer 22 by a third distance D3. In this case, the third distance D3 may be a distance from the second edge E2 to the sidewall of the third trenches T3. The fourth distance D4 may be a distance from the first edge E1 to the sidewall of the third trenches T3. If each of the third trenches T3 are disposed to be adjacent to the first edge E1 or the second edge E2, the second contact structure 26 that has been misaligned or tilted may be formed to come into contact with the source structure 21, and a bridge may occur between the second contact structure 26 and the source structure 21. Accordingly, a location of the third trenches T3 may be adjusted by considering the misalignment or tilting of the second contact structure 26. The exposure of the source structure 21 by the third trenches T3 can be reduced even though the third trenches T3 are misaligned or tilted due to the third trenches T3 having an increased third distance D3 between the second edge E2 of the insulating layer 22 and the third trenches T3. For example, the third trenches T3 may be formed so that the third distance D3 is greater than the fourth distance D4.

Next, the second contact structures 26 may be formed within the third trenches T3, respectively. The second contact structure 26 may extend through the stack 24 and may be connected to the first contact structure 23. Furthermore, the second contact structure 26 may be connected to a peripheral circuit PC through the first contact structure 23 and an interconnection structure 3. The second contact structure 26 may have the third width W3 in the first direction I and the fourth width W4 in the second direction II. In this case, the third width W3 and the fourth width W4 may be the widths of an upper surface of the second contact structure 26 or the widths of a lower surface of the second contact structure 26 or may be an average width of the widths of the upper surface and lower surface of the second contact structure 26. The third width W3 may be 1 to 2 times greater than the fourth width W4. For example, the third width W3 may be about 1.5 times greater than the fourth width W4.

Furthermore, each of the second contact structures 26 may be formed to be spaced apart from the first edge E1 of the insulating layer 22 by the fourth distance D4 and from the second edge E2 of the insulating layer 22 by the third distance D3. In this case, the third distance D3 may be a distance from the second edge E2 to the sidewall of the second contact structure 26. The fourth distance D4 may be a distance from the first edge E1 to the sidewall of the second contact structure 26. In this case, the sidewall may be the sidewall of the upper surface of the second contact structure 26, may be the sidewall of the lower surface of the second contact structure 26 or may be the sidewall of a middle surface between the upper surface and the lower surface of the second contact structure 26. Alternatively, a third distance D3 and a fourth distance D4 may each be an average distance from each of the second edge E2 and the first edge E1 to the sidewall of the second contact structure 26. In a plane view, the third distance D3 between the second edge E2 and the second contact structure 26 may varies. Also, the fourth distance D4 between the first edge E1 and the second contact structure 26 may varies. The third distance D3 may be greater than the fourth distance D4. The third distance D3 may be greater than the first distance D1. The fourth distance D4 may be greater than the second distance D2. Furthermore, the fourth distance D4 may be substantially the same as the second width W2. The second contact structure 26 may include a conductive material, such as tungsten.

Furthermore, the widths W3 and W4 of the second contact structure 26 may be substantially the same as or different from the widths W1 and W2 of the first contact structure 23. For example, the third width W3 may be smaller than the first width W1, and the fourth width W4 may be smaller than the second width W2. Misalignment between the first contact structure 23 and the second contact structure 26 can be prevented or reduced by forming the widths W3 and W4 of the second contact structure 26 to be smaller than the widths W1 and W2 of the first contact structure 23.

Fourth trenches T4 may be formed within the stack 24. The fourth trenches T4 may be for forming channel structures 28. The fourth trenches T4 may expose the cell area 21_1 of the source structure 21. Next, the channel structures 28 may be formed within the fourth trenches T4, respectively. The channel structure 28 may further include at least one of a channel layer 28A, a memory layer 28B that surrounds the sidewall of the channel layer 28A, and an insulating core 28C within the channel layer 28A. The channel layer 28A may include a semiconductor material, such as silicon or germanium. The memory layer 28B may include a blocking layer, a data storage layer, or a tunneling layer, or a combination thereof. The insulating core 28C may include an insulating material, such as oxide, nitride, or an air gap.

For reference, although not illustrated in this drawing, a stair structure may be formed by patterning the stack 24. The stair structure may be formed in the connection area 21_2 of the source structure 21. For example, the stair structure may be formed to expose each of the second material layers 24B. Furthermore, contact plugs CT that are connected to the second material layers 24B, respectively, may be formed. First, an interlayer insulating layer may be formed on the stair structure. Fifth trenches T5 that expose the second material layers 24B of the stair structure, respectively, may be formed through the interlayer insulating layer. Next, the contact plugs CT may be formed within the fifth trenches T5, respectively. Accordingly, the contact plugs CT may be connected to the second material layers 24B of the stack 24, which are exposed through the stair structure, respectively. The contact plugs CT may include a conductive material, such as tungsten.

Furthermore, the second trenches T2, the third trenches T3, the fourth trenches T4, or the fifth trenches T5 may be simultaneously formed or may be formed at different times. For example, after the second trenches T2 are formed, the third trenches T3, the fourth trenches T4, and the fifth trenches T5 may be simultaneously formed. In another example, the third trenches T3, the fourth trenches T4, and the fifth trenches T5 may be sequentially formed.

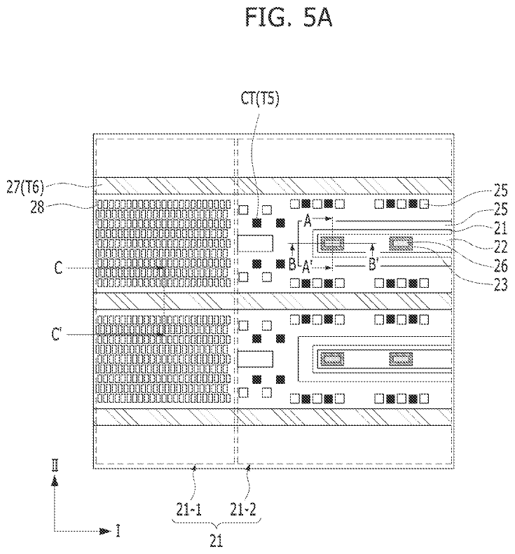

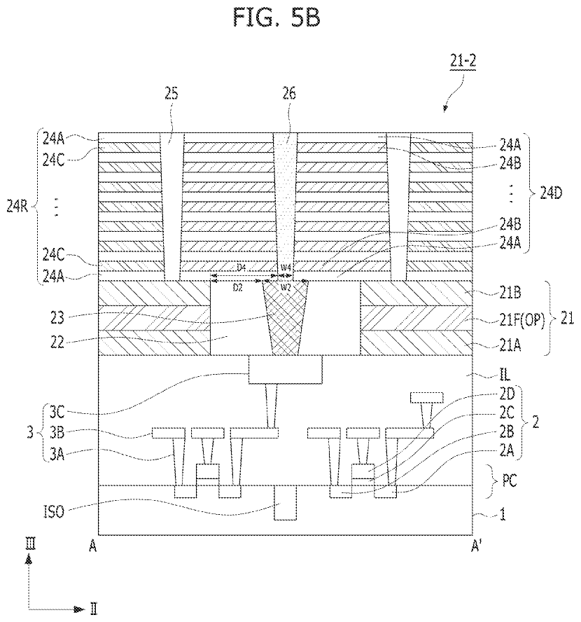

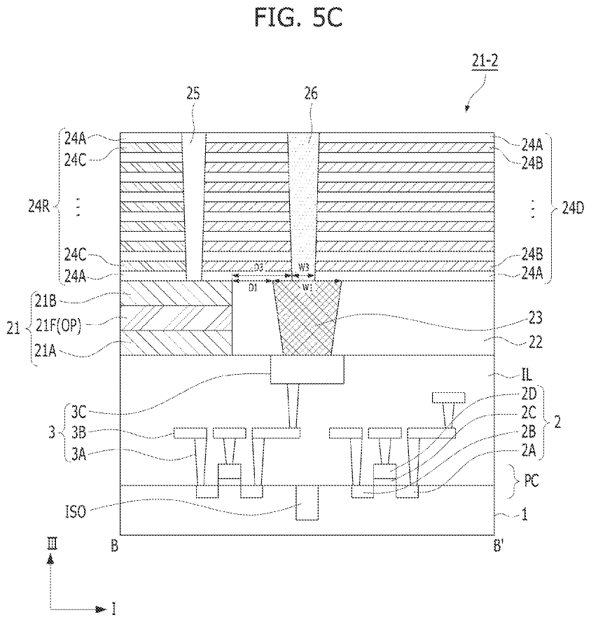

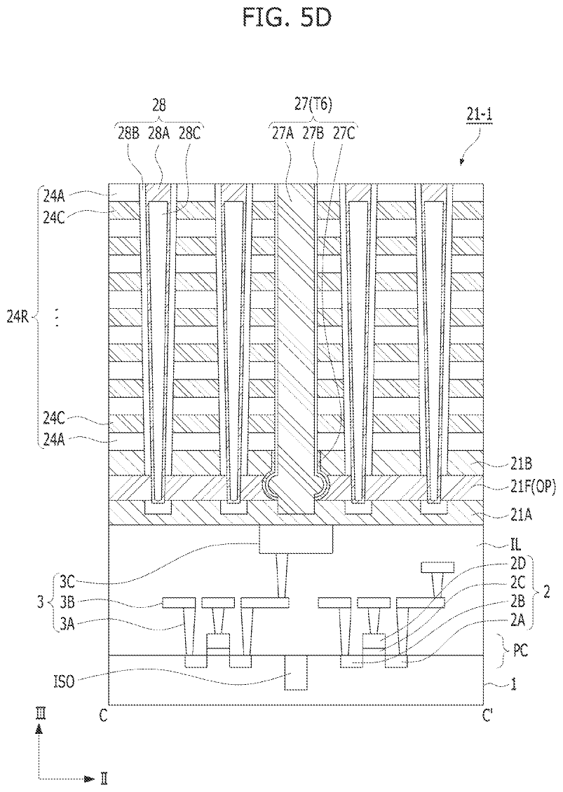

Referring to FIGS. 5A to 5D, a source contact structure 27 may be formed. For example, after a source sacrificial layer 21C is substituted with a third source layer 21F, a source contact structure 27 that is connected to a cell area 21_1 of a source structure 21 may be formed. The source contact structure 27 may extend up to the connection area 21_2.

First, a sixth trench T6 that exposes the source structure 21 may be formed through a stack 24. In this case, a first source passivation layer may be formed on the sidewall of a second source layer 21B that is exposed in the process of forming the sixth trench T6. Next, the source sacrificial layer 21C may be exposed by etching a second passivation layer 21E that is exposed at the bottom of the sixth trench T6. Next, an opening OP may be formed by removing the source sacrificial layer 21C. Next, a channel layer 28A may be exposed by etching the memory layer 28B that has been exposed through the opening OP. In the process of etching the memory layer 28B, a part of a first passivation layer 21D, the second passivation layer 21E, or the first source passivation layer may be removed. Accordingly, each of the channel structures 28 may be connected to the source structure 21.

Next, after a conductive layer is formed within the sixth trench T6 and the opening OP, a portion that belongs to the conductive layer and that has been formed within the sixth trench T6 may be removed. Accordingly, a portion that belongs to the conductive layer and that remains within the opening OP may be defined as a third source layer 21F. Next, a second source passivation layer may be formed on the sidewall of the third source layer 21F that has been exposed through the sixth trench T6 and a surface of the first source layer 21A. The second source passivation layer may be defined as a second spacer 27C along with the first source passivation layer. Next, a first spacer 27B may be formed within the sixth trench T6. Next, a first source layer 21A may be exposed by etching the bottom of the second spacer 27C and the first spacer 27B. Next, a source contact plug 27A may be formed within the sixth trench T6.

The stack 24 that has been formed in the cell area 21_1 of the source structure 21 may be substituted with a gate structure 24R. Second material layers 24B of the stack 24 may be substituted with third material layers 24C. For example, the second material layers 24B may be substituted with the third material layers 24C by removing the second material layers 24B through the sixth trench T6. If first material layers 24A include an insulating material and the second material layers 24B include a sacrificial material, the second material layers 24B may be substituted with conductive layers. The conductive layers may include a conductive material, such as polysilicon, tungsten, or molybdenum. If the first material layers 24A include an insulating material and the second material layers 24B include a conductive material, the second material layers 24B may be silicided. Accordingly, the gate structure 24R in which the first material layers 24A and the third material layers 24C have been alternately stacked may be defined. In this case, the stack 24 that remains without being substituted with the gate structure 24R may be defined as the dummy structure 24D.

For reference, in the process of substituting the second material layers 24B with the third material layers 24C, a support 25 can prevent the dummy structure 24D or the gate structure 24R from being tilted or reduce the tilting of the dummy structure 24D or the gate structure 24R. The second material layers 24B on one side of the support 25 may be substituted with the third material layers 24C. The second material layers 24B on the other side of the support 25 may remain.

According to the aforementioned manufacturing method, the third width W3 of each of the third trenches T3 for forming the second contact structure 26 may have a form in which the third width W3 is greater than the fourth width W4. Accordingly, if the second contact structure 26 is formed by forming the third trenches T3 having a great aspect ratio, the second contact structure 26 can be prevented from being offset or tilted in the second direction II.

Furthermore, the third trenches T3 may be formed so that the third distance D3 is greater than the fourth distance D4. Accordingly, although the second contact structure 26 is offset and formed or tilted in the first direction I, the occurrence of a bridge between the second contact structure 26 and the source structure 21 can be prevented or reduced.

Although embodiments according to the technical spirit of the present disclosure have been described above with reference to the accompanying drawings, the embodiments have been provided to merely describe embodiments according to the concept of the present disclosure, and the present disclosure is not limited to the embodiments. A person having ordinary knowledge in the art to which the present disclosure pertains may substitute, modify, and change the embodiments in various ways without departing from the technical spirit of the present disclosure written in the claims. Such substitutions, modifications, and changes may be said to belong to the scope of the present disclosure.

What is claimed is:

1. A semiconductor device comprising:
a source structure;
an insulating layer disposed within the source structure, the insulating layer comprising a first edge that extends in a first direction and a second edge that extends in a second direction, the second direction intersecting the first direction;
a first contact structure disposed within the insulating layer, the first contact structure having a second width in the second direction and a first width in the first direction, the first width being greater than the second width; and
a second contact structure disposed on the insulating layer and connected to the first contact structure, the second contact structure having a fourth width in the second direction and a third width in the first direction, the third width being greater than the fourth width.

2. The semiconductor device of claim 1, wherein the first contact structure has a second distance from the first edge in the second direction and a first distance from the second edge in the first direction, which is greater than the second distance.

3. The semiconductor device of claim 2, wherein the second distance is substantially identical with the second width.

4. The semiconductor device of claim 1, wherein the second contact structure is disposed to be spaced apart from the first edge by a fourth distance and to be spaced apart from the second edge by a third distance greater than the fourth distance.

5. The semiconductor device of claim 4, wherein the fourth distance is substantially identical with the second width.

6. The semiconductor device of claim 1 further comprises:
the source structure including a cell area and a connection area, a gate structure being disposed in the cell area of the source structure;
channel structures that extend through the gate structure and that are connected to the cell area of the source structure; and
a dummy structure disposed in the connection area of the source structure.

7. The semiconductor device of claim 6, wherein the second contact structure, extending through the dummy structure, is connected to the first contact structure.

8. The semiconductor device of claim 1,
wherein the third width is smaller than the first width, and
wherein the fourth width is smaller than the second width.

9. The semiconductor device of claim 1, wherein the first width is 1 to 2 times greater than the second width.

10. The semiconductor device of claim 1, wherein the third width is 1 to 2 times greater than the fourth width.

11. A semiconductor device comprising:
a peripheral circuit;
a source structure disposed on the peripheral circuit;
an insulating layer disposed within the source structure, the insulating layer comprising a first edge that extends in a first direction and a second edge that extends in a second direction, the second direction intersecting the first direction;
a first contact structure that is connected to the peripheral circuit through the insulating layer and that is disposed to be spaced apart from the first edge by a second distance and to be spaced apart from the second edge by a first distance, the first distance being greater than the second distance; and
a second contact structure that is disposed on the insulating layer, that is connected to the first contact structure, and that is disposed to be spaced from the first edge by a fourth distance and to be spaced from the second edge by a third distance, the third distance being greater than the fourth distance.

12. The semiconductor device of claim 11, wherein the first contact structure has a second width in the second direction and a first width in the first direction, the first width being greater than the second width.

13. The semiconductor device of claim 12, wherein the second width is substantially identical with the second distance.

14. The semiconductor device of claim 12, wherein the first width is 1 to 2 times greater than the second width.

15. The semiconductor device of claim 12, wherein the second contact structure has a fourth width in the second direction and a third width in the first direction, the third width being greater than the fourth width.

16. The semiconductor device of claim 15,
wherein the third width is smaller than the first width, and
wherein the fourth width is smaller than the second width.

17. The semiconductor device of claim 15, wherein the third width is 1 to 2 times greater than the fourth width.

18. The semiconductor device of claim 12, wherein the fourth distance is substantially identical with the second width.

19. The semiconductor device of claim 11 further comprises:
the source structure including a cell area and a connection area, a gate structure being disposed in the cell area of the source structure;
channel structures that extend through the gate structure and that are connected to the cell area of the source structure; and
a dummy structure disposed in the connection area of the source structure.

20. The semiconductor device of claim 19, wherein the second contact structure, extending through the dummy structure, is connected to the first contact structure.

21. A method of manufacturing a semiconductor device, comprising:
forming a source structure;
forming, within the source structure, an insulating layer comprising a first edge that extends in a first direction and a second edge that extends in a second direction, the second direction intersecting the first direction;
forming, within the insulating layer, a first contact structure having a second width in the second direction and a first width in the first direction, the first width being greater than the second width;
forming a stack on the source structure; and
forming a second contact structure that extends through the stack and is connected to the first contact structure, the second contact structure having a fourth width in the second direction and a third width in the first direction, the third width being greater than the fourth width.

22. The method of claim 21, wherein the first contact structure is formed to be spaced apart from the first edge by a second distance and to be spaced apart from the second edge by a first distance, the first distance being greater than the second distance.

23. The method of claim 22, wherein the second distance is substantially identical with the second width.

24. The method of claim 22, wherein the second contact structure is formed to be spaced apart from the first edge by a fourth distance and to be spaced apart from the second edge by a third distance, the third distance being greater than the fourth distance.

25. The method of claim 24, wherein the fourth distance is substantially identical with the second width.

26. The method of claim 21,
wherein the source structure comprises a cell area and a connection area, and
wherein the method further comprises forming channel structures that extend through the stack and that are connected to the cell area of the source structure.

27. The method of claim 21, wherein the first width is 1 to 2 times greater than the second width.

28. The method of claim 21,
wherein the third width is smaller than the first width, and
wherein the fourth width is smaller than the second width.

29. The method of claim 21, wherein the third width is 1 to 2 times greater than the fourth width.

30. A method of manufacturing a semiconductor device, comprising:
forming a peripheral circuit;
forming a source structure on the peripheral circuit;
forming, within the source structure, an insulating layer comprising a first edge that extends in a first direction and a second edge that extends in a second direction, the second direction intersecting the first direction;
forming a first contact structure that is connected to the peripheral circuit through the insulating layer and that is disposed to be spaced apart from the first edge by a second distance and to be spaced apart from the second edge by a first distance, the first distance being greater than the second distance;
forming a stack on the source structure; and
forming a second contact structure that extends through the stack and is connected to the first contact structure, the second contact structure being disposed to be spaced apart from the first edge by a fourth distance and that is disposed to be spaced apart from the second edge by a third distance, the third distance being greater than the fourth distance.

31. The method of claim 30, wherein the first contact structure has a second width in the second direction and a first width in the first direction, the first width being greater than the second width.

32. The method of claim 31, wherein the second width is substantially identical with the second distance.

33. The method of claim 31, wherein the first width is 1 to 2 times greater than the second width.

34. The method of claim 31, wherein the fourth distance is substantially identical with the second width.

35. The method of claim 31, wherein the second contact structure has a fourth width in the second direction and a third width in the first direction, is the third width being greater than the fourth width.

36. The method of claim 35,
wherein the third width is smaller than the first width, and
wherein the fourth width is smaller than the second width.

37. The method of claim 35, wherein the third width is 1 to 2 times greater than the fourth width.

38. The method of claim 30,
wherein the source structure comprises a cell area and a connection area, and
wherein the method further comprises forming channel structures that extend through the stack and that are connected to the cell area of the source structure.
